(19) United States
(12) Patent Application Publication
(10) Pub. No.: US 2013/0026630 A1
(43) Pub. Date: Jan. 31, 2013

(54) FLIP CHIPS HAVING MULTIPLE SOLDER BUMP GEOMETRIES

(71) Applicant: ChauChin Low, Fremont, CA (US)

(72) Inventor: ChauChin Low, Fremont, CA (US)

(21) Appl. No.: 13/191,632

(22) Filed: Jul. 27, 2011

(51) Int. Cl. H01L 23/498; H01L 21/60

(52) U.S. Cl. 257/738; 438/613; 257/E23.069; 257/E21.508

(57) ABSTRACT

In certain embodiments, a flip chip includes a first and second solder bump. The first solder bump has a solder bump height that is greater than the second solder bump.

In certain embodiments, a method includes depositing solder on an integrated circuit, reflowing the solder to create at least two solder bumps between bond pads and the integrated circuit, wherein the at least two solder bumps have different solder bump heights. A bottom layer is sized to accommodate the different solder bump heights.

### SUMMARY

Certain embodiments of the present invention are generally directed to devices and methods that include flip chips with multiple solder bump geometries.

In certain embodiments, a flip chip includes a first and second solder bump. The first solder bump has a solder bump height that is greater than the second solder bump. A bottom layer is sized to accommodate the different solder bump heights.

In certain embodiments, a method includes depositing solder on an integrated circuit, reflowing the solder to create at least two solder bumps between bond pads and the integrated circuit, wherein the at least two solder bumps have different solder bump heights.

### BRIEF DESCRIPTION OF THE DRAWINGS

FIG. 1 provides a side view of an exemplary pre-assembled flip chip, in accordance with certain embodiments of the present disclosure.

FIG. 2 provides a top view of the exemplary pre-assembled flip chip of FIG. 1.

FIG. 3 provides a side view of an exemplary flip chip, in accordance with certain embodiments of the present disclosure.

FIG. 4 provides a close-up view of a portion of the flip chip of FIG. 3.

FIG. 5 provides a side view of an exemplary pre-assembled flip chip, in accordance with certain embodiments of the present disclosure.

FIG. 6 provides a close-up view of a portion of the pre-assembled flip chip of FIG. 5.

FIG. 7 provides a side view of an exemplary flip chip, in accordance with certain embodiments of the present disclosure.

FIG. 8 provides a close-up view of a portion of the flip chip of FIG. 7.

### DETAILED DESCRIPTION

The present disclosure generally relates to solder bumps that establish an electrical interconnection between opposing layers of a single or multi-layer circuit. Making such solder bump interconnections can be complicated by the use of boards having multiple level surface layers, interconnect pads that may take advantage of interconnections having different electrical properties (e.g., different conductivities), and so forth. In recognition of these challenges, the present disclosure provides devices and methods that include flip chips with multiple solder bump geometries.

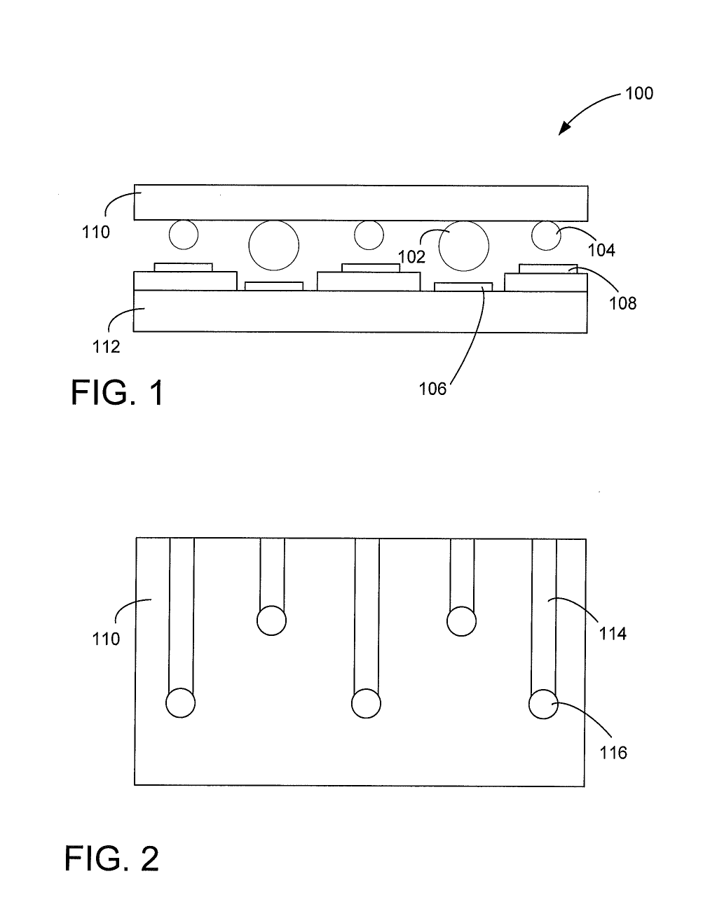

FIG. 1 provides a side view of a pre-assembled flip chip 100 having a first solder ball 102, second solder ball 104, first bond pad 106, second bond pad 108, top layer 110, and bottom layer 112. As shown in FIG. 1, the first solder ball 102 has a greater diameter than the second solder ball 104. The top layer 110, as shown in FIG. 2, is an integrated circuit having a plurality of traces 114 and electrodes or vias 116. Any number of individual traces and other conductive features can be formed on the top layer 110. Such features may be localized or may extend the full length of the top layer 110. Discrete components such as multi-pin electrical connectors, integrated circuits, resistors, capacitors, stiffeners, etc. can also be incorporated into the top layer or integrated circuit 110 as required. The bottom layer 112 is a substrate having bond pads 106, 108 at different planes or levels.

The flip chip 100 is assembled by reflowing the solder balls 102, 104 to mechanically and electrically interconnect the top and bottom layers 110, 112. Any suitable process that heats the solder causing it to melt, and then allows the material to subsequently cool and harden can be used. Examples include but are not limited to a wave solder machine, an infrared heater, a forced hot air conduction system, an oven, a soldering iron, etc. Other solder connections in a flip chip can be concurrently formed at this time.

After reflow, the solder balls 102, 104 become solder bumps, where each individual solder bump can be electrically coupled to a respective individual bond pad. The solder bumps provide conductive pathways between the layers to accommodate a wide range of signal types and signal strengths. For reference, the term “solder” will be broadly understood to describe any number of conductive materials, metals and/or alloys that are reflowed from an initial shape to a final solid state to establish an electrical interconnection path, Also for reference, the term “solder ball” refers to pre-reflow solder and the term “solder bump” refers to post-reflow solder in a flip chip. For example, solder balls take the form of solder bumps after the solder balls are reflowed or melted. Although not shown in FIG. 1, additional layers including insulative and conductive material can be incorporated into the flip chip 100. Further, the flip chip 100 can be implemented into several circuit assemblies, for example flex circuits used in printed circuit cable assemblies.

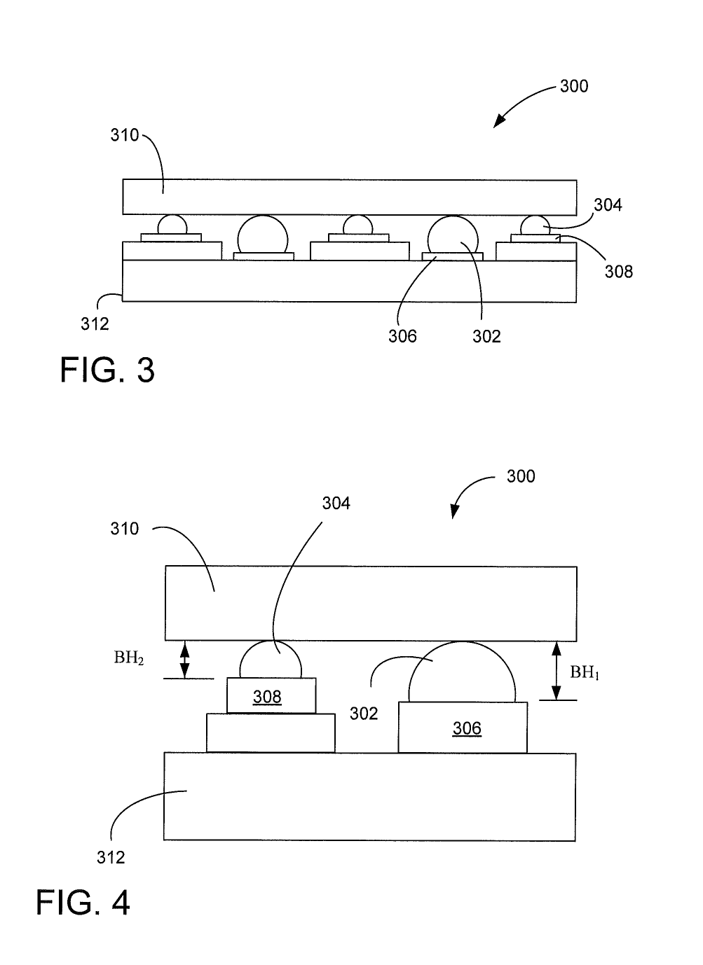

FIG. 3 provides a side view of a post-reflow flip chip 300 having a first solder bump 302, second solder bump 304, first bond pad 306, second bond pad 308, top layer 310, and bottom layer 312. The first solder bump 302 is electrically and mechanically coupled to the first bond pad 306 and the top layer 310, which can include electrical traces or vias. The second solder bump 304 is electrically and mechanically coupled to the second bond pad 308 and the top layer 310. The first and second bond pads 306, 308 are positioned on the bottom layer 312 at different levels. The bottom layer 312 is sized and positioned to accommodate the different sized solder bumps and multiple levels at which the bond pads 306, 308 are positioned.

As shown in FIG. 4, the first solder bump 302 has a first bump height (BH₁) and the second solder bump 304 has a second bump height (BH₂). For reference, bump height refers to the height of a solder bump between a bond pad and a bottom side of a top layer or integrated circuit. As shown in FIG. 4, the first bump height (BH₁) is greater than the second bump height (BH₂). This arrangement of multiple solder bump geometries permits design flexibility by enabling a reduction in the number of solder bumps in a given flip chip. For example, a larger solder bump can be used for interconnects that supply power to the top layer 310 and therefore use higher current than other interconnects. Further, the larger solder bumps can replace two or more smaller solder bumps, thereby reducing the number of solder bumps and the size of the flip chip and/or circuitry. Although not shown in FIG. 3, additional layers including insulative and conductive material can be incorporated into the flip chip 100.

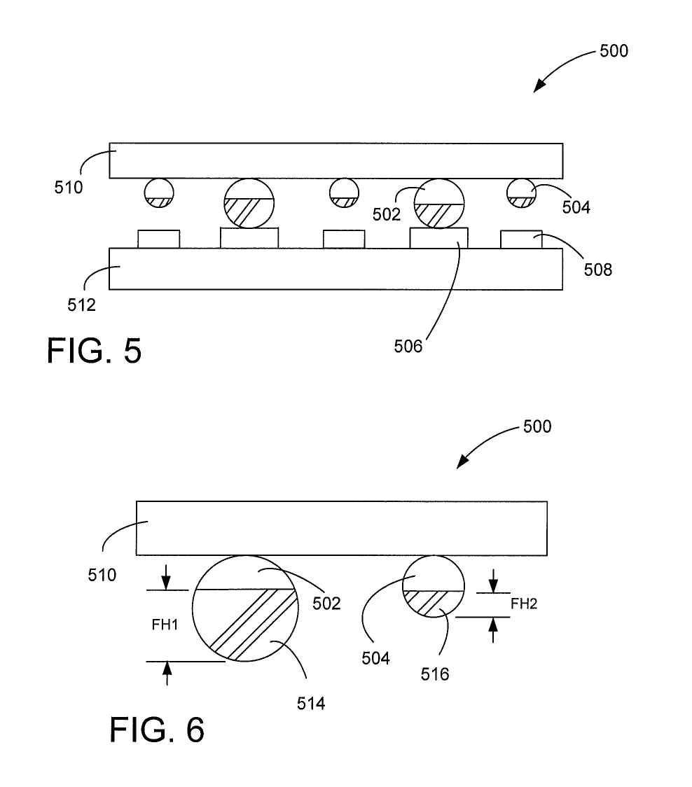

FIG. 5 provides a side view of a pre-assembled flip chip 500 having a first solder ball 502, second solder ball 504, first bond pad 506, second bond pad 508, top layer 510, and bottom layer 512, As shown in FIG. 5, the first solder ball 502 has a greater diameter than the second solder ball 504. The top layer 510 can be an integrated circuit having a plurality of traces and electrodes or vias. The bottom layer 512 can be a substrate having bond pads 506, 508 on or at the same plane. Although not shown in FIG. 5, additional layers including insulative and conductive material can be incorporated into the flip chip 500.

The flip chip 500 is assembled by reflowing the solder balls 502, 504 to mechanically and electrically interconnect the top and bottom layers 510, 512. After reflow, the solder balls 502, 504 become solder bumps, for which each individual solder bump can be mechanically and electrically coupled to a respective individual bond pad and individual trace, electrode, or via in the top layer 510.

FIG. 6 provides a close-up view of a portion of the pre-assembled flip chip 500 of FIG. 5. As shown in FIG. 6, each solder ball 502, 504 has a tacky flux portion 514, 516 having a tacky flux height (FH₁, FH₂). Tacky flux can be a gel-like flux on the solder balls 502, 504 where the flux will remove an oxide layer of a substrate surface, thereby enabling a good solder joint during a reflow process. Here, the tacky flux heights are the same and can be established by setting the tacky flux heights equal to what would be required for the smaller solder ball, shown as the second solder ball 504.

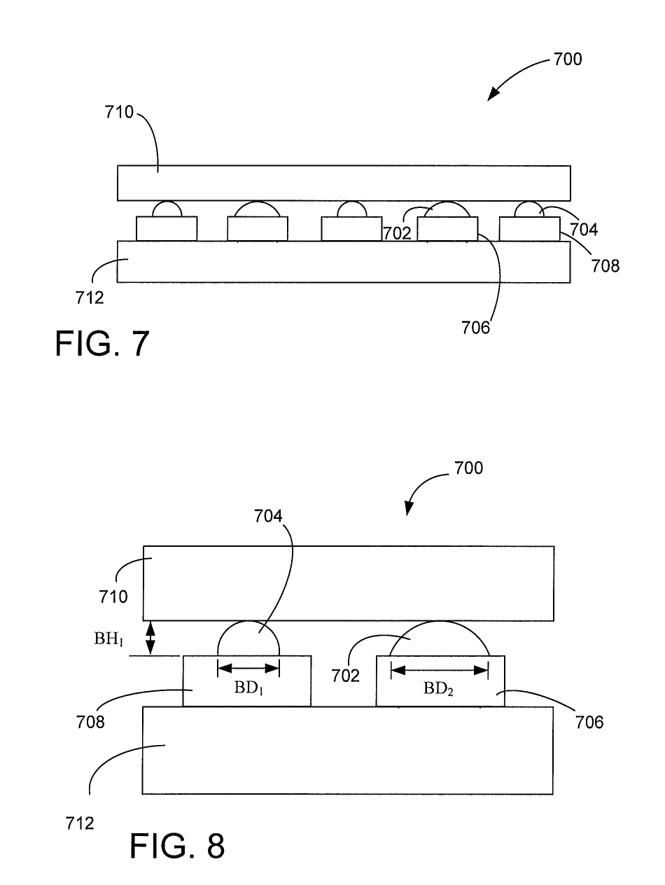

FIG. 7 provides a side view a flip chip 700 having a first solder bump 702, second solder bump 704, first bond pad 706, second bond pad 708, top layer 710, and bottom layer 712. The first solder bump 702 is electrically and mechanically coupled to the first bond pad 706 and the top layer 710, which can include electrical traces or vias. The second solder bump 704 is electrically and mechanically coupled to the second bond pad 708 and the top layer 710. As shown in FIG. 8, the first solder bump 702 has a first bump diameter (BD₁) and the second solder bump 704 has a second bump diameter (BD₂), while each solder bump has the same height. The first bump diameter (BD₁) is greater than the second bump diameter (BD₂). This arrangement of multiple solder bump diameters permits design flexibility by enabling a reduction in the number of solder bumps in a given flip chip. For example, a larger solder diameter can be used for interconnects that supply power to the top layer 710 and therefore use higher current than other interconnects. Further, the larger solder bumps can replace two smaller solder bumps, thereby reducing the number of solder bumps and the size of the flip chip and/or circuitry. Although not shown in FIG. 7, additional layers including insulative and conductive material can be incorporated into the flip chip 700.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

1. A flip chip comprising:
a first solder bump electrically coupled to an integrated circuit and a first bond pad of a bottom layer;
a second solder bump electrically coupled to the integrated circuit and a second bond pad of the bottom layer, the first solder bump having a solder bump height greater than the second solder bump; and
the bottom layer sized to accommodate the different solder bump heights.

2. The flip chip of claim 1, wherein the first bond pad is at a first plane and the second bond pad is at a second plane different from the first plane.

3. The flip chip of claim 2, wherein the bond pads are copper.

4. The flip chip of claim 2, wherein the integrated circuit includes traces electrically coupled to the solder bumps.

5. The flip chip of claim 1, wherein the first bond pad is configured to transmit an electrical power signal to the flip chip.

6. (canceled)

7. The flip chip of claim 1, wherein the flip chip is implemented in a printed circuit cable assembly.

8. The flip chip of claim 1, wherein the first and second solder bumps are mechanically coupled to the integrated circuit and the respective bond pads.

9. An apparatus comprising:
a circuit having a first and second solder balls, the first solder ball having a diameter greater than the second solder ball,
wherein the first and second solder balls have equal tacky flux heights.

10. The apparatus of claim 9, wherein the first and second solder balls are mechanically coupled to the first and second bond pads, respectively.

11. The apparatus of claim 10, wherein the bonds pads are located on a single plane.

12. The apparatus of claim 9, wherein the apparatus is a flip chip implemented in a printed circuit cable assembly.

13. A method comprising:
depositing at least two solder balls having different diameters on an integrated circuit;
reflowing the solder balls to create a first solder bump electrically coupled to a first bond pad and the integrated circuit and a second solder bump electrically coupled to a second bond pad and the integrated circuit; and
wherein the first and second solder bumps have different solder bump heights.

14. The method of claim 13, wherein the bond pads are copper.

15. The method of claim 13, wherein the first and second solder balls have equal tacky flux heights.

16. The method of claim 13, wherein the first and second bond pads are located at different planes on a bottom layer.

17. The method of claim 13, wherein the first bond pad transmit electrical power to the integrated circuit.

18. The method of claim 13, wherein the reflowing step mechanically couples the first and second solder bumps to first and second bond pad, respectively.

19. The flip chip of claim 1, wherein the first solder bump is configured to transmit a higher current than the second solder bump.
